(19) United States
(12) Patent Application Publication
(10) Pub. No.: US 2011/0024174 A1
(43) Pub. Date: Feb. 3, 2011

(54) CAPACITOR MOUNTING METHOD AND PRINTED CIRCUIT BOARD

(76) Inventor: Hidetaka Ootsuka, Tokyo (JP)

Correspondence Address: Mr. Jackson Chen, 6535 N. STATE HWY 161, IRVING, TX, 75039, US

(21) Appl. No.: 12/816,446

(22) Filed: Jun. 16, 2010

(30) Foreign Application Priority Data
Jul. 31, 2009 (JP) 2009-179183

(51) Int. Cl. H05K 1/18; H05K 3/34

(52) U.S. Cl. 174/260; 29/840

(57) ABSTRACT

Provided is a capacitor mounting method for mounting a capacitor in close proximity to an LSI, which includes mounting the capacitor on top of the LSI with solder balls (bumps) placed therebetween, the LSI mounted on top of a printed circuit board with solder balls (bumps) placed therebetween, in a stacked fashion. This enables a decoupling capacitor to be mounted in close proximity to the LSI without affecting power supply or a signal line

### INCORPORATION BY REFERENCE

This application is based upon and claims the benefit of priority from Japanese patent application No. 2009-179183, filed on Jul. 31, 2009, the disclosure of which is incorporated herein in its entirety by reference.

### BACKGROUND OF THE INVENTION

1. Field of the Invention

The present invention relates to a capacitor mounting method and a printed circuit board and, particularly, to a method of mounting a capacitor on a printed circuit board with an embedded LSI, and a printed circuit board on which a capacitor is mounted by using the capacitor mounting method.

2. Description of Related Art

In the case of mounting a large scale integration (LSI) that operates at high frequency on a printed circuit board for use, a decoupling capacitor that absorbs noise is generally placed in close proximity to the LSI so as to prevent malfunction due to switching noise or the like (cf. Japanese Unexamined Patent Application Publication No.2004-214509). As one technique of placing a decoupling capacitor with low inductance in close proximity to an LSI, a stack structure in which a thin-film capacitor is interposed between an LSI and a printed circuit board is used.

From the viewpoint of power supply design, the technique enables the LSI and the capacitor to be connected without through the printed circuit board, so that the inductance is very low, which is advantageous in terms of AC. In terms of DC, on the other hand, the technique has a problem that IR drop (voltage drop due to a resistance component) increases caused by the addition of a via hole penetrating the capacitor. Thus, the technique both has the merit in terms of AC and the demerit in terms of DC, and the effect of improving power supply noise is not sufficiently obtained.

Further, from the viewpoint of a signal line, the technique also has the demerit that, because a signal line passes through a capacitor with a high dielectric constant, a signal is significantly attenuated, leading to degradation of signal quality. This is described hereinafter with reference to FIGS. 3 and 4. FIG. 3 is a cross-sectional view showing an example of mounting a thin-film capacitor according to related art. FIG. 4 is an equivalent circuit diagram of a power system in the example of mounting a capacitor shown in FIG. 3.

As shown in FIG. 3, a capacitor 23 according to related art is mounted in such a way that it is interposed between a printed circuit board 21 and an LSI 22. The LSI 22 and the capacitor 23 respectively have power supply grounds connected to each other with a solder ball 24 placed therebetween and have signal lines connected to each other with a solder ball 26 placed therebetween. Further, the capacitor 23 and the printed circuit board 21 respectively have power supply grounds connected to each other with a solder ball 25 placed therebetween and have signal lines connected to each other with a solder ball 27 placed therebetween.

FIG. 4 shows an equivalent circuit of a power system in this example. In FIG. 4, R1 is a resistance component on the power supply side of the printed circuit board 21 or the like, L1 is an inductance component on the power supply side of the printed circuit board 21 or the like, R3 is a resistance component on the ground side of the printed circuit board 21 or the like, and L3 is an inductance component on the ground side of the printed circuit board 21 or the like. Further, R2 is a parasitic resistance component on the power supply side of the capacitor 23, L2 is a parasitic inductance component on the power supply side of the capacitor 23, R4 is a parasitic resistance component on the ground side of the capacitor 23, and L4 is a parasitic inductance component on the ground side of the capacitor 23. Note that C1 is the capacitor 23, and C2 is a capacitor that is mounted On the printed circuit board 21, though not shown in FIG. 3.

A current i that is supplied from a power supply (VDD) terminal to the LSI 22 passes through R1, L1, R2 and L2, and then through L4, R4, L3 and R3, and returns to a ground (GND) terminal. Because DC IR drop V_{dc} at this time is determined by the product of the resistance components and the current, it is calculated by V_{dc}=(R1+R2+R3+R4)×i. Note that IR drop V_{dc2} when the capacitor 23 does not exist is V_{dc2}=(R1+R3)×i since there is no R2 and R4. Therefore, there is a problem that the power supply characteristics are degraded by the amount of the parasitic resistances R2 and R4 of the capacitor 23.

Further, the loop inductance between the capacitor (C2) on the printed circuit board 21 and the LSI 22 is (L1+L2+L3+L4), and there is a problem that the parasitic components of the capacitor 23 (C1) are added and the effect of the capacitor (C2) is degraded.

Further, in a signal line, there is a problem that dielectric loss increases by passing through the capacitor 23 with a high dielectric constant compared to the case where the capacitor 23 does not exist, which causes degradation of signal quality.

Although a method of connecting a capacitor between an LSI and a printed circuit board by flip-chip bonding with use of a capacitor-mounted board is disclosed in Japanese Unexamined Patent Application Publication No. 2004-214509, the method does not allow prevention of the IR drop or the inductance degradation.

### SUMMARY

In light of the foregoing, an exemplary object of the invention is to provide a capacitor mounting method that enables a decoupling capacitor to be mounted in close proximity to an LSI without affecting power supply or a signal line, and a printed circuit board.

In an exemplary aspect of the invention, a capacitor mounting method for mounting a capacitor in close proximity to an LSI includes mounting the capacitor on top of the LSI with solder balls or bumps placed therebetween, the LSI mounted on top of a printed circuit board with solder balls or bumps placed therebetween, in a stacked fashion.

According to the exemplary aspect of the invention described above, it is possible to provide a capacitor mounting method that enables a decoupling capacitor to be mounted in close proximity to an LSI without affecting power supply or a signal line, and a printed circuit board.

### BRIEF DESCRIPTION OF THE DRAWINGS

The above and other aspects, features, and advantages of the present invention will become more apparent from the following description of certain exemplary embodiments when taken in conjunction with the accompanying drawings, in which:

FIG. 1 is a cross-sectional view showing a capacitor mounting method according to an exemplary embodiment of the invention;

FIG. 2 is an equivalent circuit diagram of a power system in the capacitor mounting method according to the exemplary embodiment;

FIG. 3 is a cross-sectional view showing an example of mounting a thin-film capacitor according to related art; and

FIG. 4 is an equivalent circuit diagram of a power system in the example of mounting a capacitor shown in FIG. 3.

### EXEMPLARY EMBODIMENT

An exemplary embodiment of the present invention will be described hereinbelow with reference to the drawings. The following description and the attached drawings are appropriately shortened and simplified to clarify the explanation.

A capacitor mounting method and a printed circuit board according to an exemplary embodiment of the present invention are described hereinafter with reference to FIG. 1. FIG. 1 is a cross-sectional view showing a capacitor mounting method according to the exemplary embodiment. FIG. 1 shows a cross section of an LSI-embedded printed circuit board on which a capacitor is mounted.

In FIG. 1, a thin-film LSI 12 has solder balls (or bumps) 14 and 16 on one surface of an opposed pair of surfaces and has solder balls 15 and 17 on the other surface.

The LSI 12 is connected to a printed circuit board 11 with the solder balls 15 and 17 placed therebetween. Specifically, the LSI 12 and the printed circuit board 11 respectively have power supplies or grounds connected to each other with the solder ball 15 placed therebetween and have signal lines connected to each other with the solder ball 17 placed therebetween. On the other hand, the LSI 12 is connected to a thin-film capacitor 13 with the solder balls 14 and 16 placed therebetween. Specifically, the LSI 12 and the capacitor 13 respectively have power supplies or grounds connected to each other with the solder balls 14 and 16 placed therebetween.

In this manner, the capacitor 13 according to the exemplary embodiment is mounted so that it is connected to the surface of the LSI 12 on the opposite side of the surface connected to the printed circuit board 11. Thus, a stack structure is formed in which the LSI 12 is interposed between the capacitor 13 and the printed circuit board 11. Note that the LSI 12 may be sealed in a package, not limited to bare-chip mounting, as long as a three-dimensional stack structure is formed.

Switching noise ΔV is represented as ΔV=Ri+L×di/dt, where R is a resistance component of the power system+ESR (parasitic resistance) of the capacitor, i is a current supplied to the LSI, and L is an inductance component of the power system+ESL (parasitic inductance) of the capacitor. It is necessary to reduce the values of R and L in order to reduce the switching noise ΔV.

In this exemplary embodiment, as shown in FIG. 1, DC power supply from the printed circuit board 11 is provided only through the solder ball 15, and a connection can be made with the power system resistance equal to the case where the capacitor 13 does not exist. Accordingly, the IR drop is small, and the power supply characteristics are improved.

Further, because power supply from the decoupling capacitor 13 is provided through the solder ball 16 in addition to the solder ball 14, the AC power supply characteristics are also improved. Furthermore, because a signal line is directly connected to the printed circuit board 11 through the solder ball 17, it does not interfere with the capacitor 13 with a high dielectric constant. It is thus possible to mount the capacitor 13 without causing degradation of signal quality.

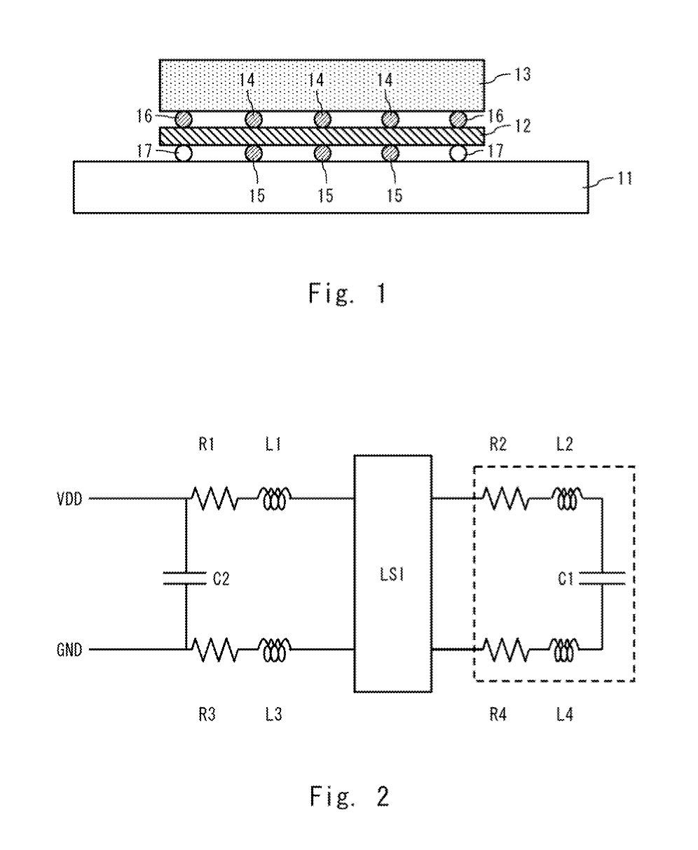

This is described in further detail with reference to FIG. 2. FIG. 2 is an equivalent circuit diagram of a power system in the capacitor mounting method according to the exemplary embodiment. In FIG. 2, R1 is a resistance component on the power supply side of the printed circuit board 11 or the like, L1 is an inductance component on the power supply side of the printed circuit board 11 or the like, R3 is a resistance component on the ground side of the printed circuit board 11 or the like, and L3 is an inductance component on the ground side of the printed circuit board 11 or the like. Further, R2 is a parasitic resistance component on the power supply side of the capacitor 13, L2 is a parasitic inductance component on the power supply side of the capacitor 13, R4 is a parasitic resistance component on the ground side of the capacitor 13, and L4 is a parasitic inductance component on the ground side of the capacitor 23. Note that C1 is the capacitor 13, and C2 is a capacitor that is mounted on the printed circuit board 11, though not shown in FIG. 1.

In this exemplary embodiment, a current i that is supplied from a power supply (VDD) terminal to the LSI 12 passes through R1 and L1, and then through L3 and R3, and returns to a ground (GND) terminal. DC IR drop V_{dc} at this time is determined by the product of the resistance components and the current. Thus, the DC IR drop V_{dc} that occurs when the current i is supplied from the power supply (VDD) terminal to the LSI 12 and then returns to the ground (GND) terminal is V_{dc}=(R1+R3)×i. It is thus possible to supply power without being affected by the parasitic resistance components R2 and R4 of the capacitor 13. Further, AC switching noise ΔV is ΔV=(R2+R4)×i+(L2+L4)×di/dt.

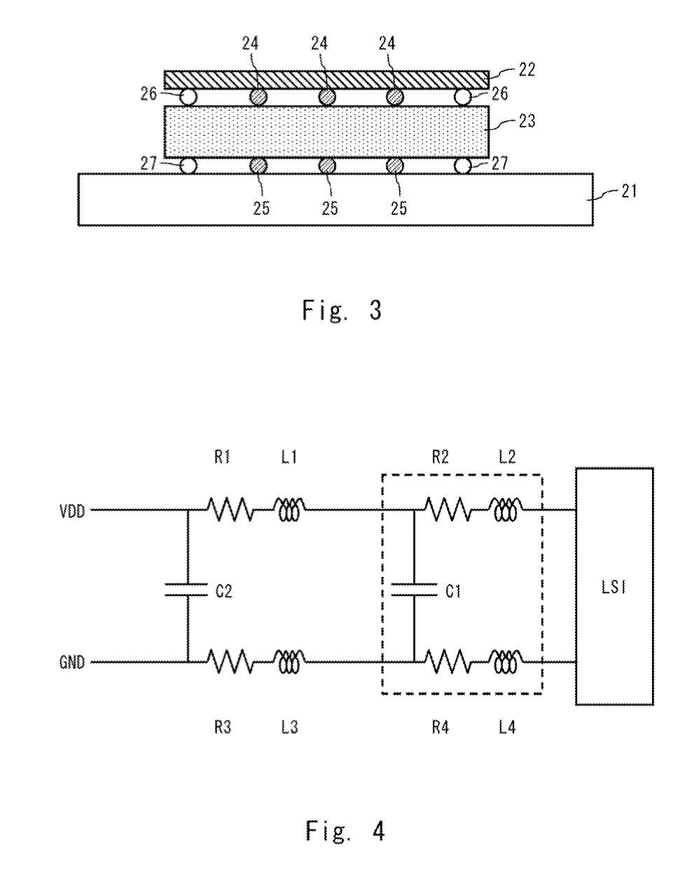

On the other hand, in the capacitor mounting method according to related art shown in FIGS. 3 and 4, the DC IR drop V_{dc} that occurs when the current i is supplied from the power supply (VDD) terminal to the LSI 12 and then returns to the ground (GND) terminal is V_{dc}=(R1+R2+R3+R4)×i as described earlier. Further, the AC drop, or AC switching noise ΔV, is ΔV=(R2+R4)×i+(L2+L4)×di/dt.

Therefore, the use of the capacitor mounting method according to the exemplary embodiment enables improvement of the DC power supply characteristics while maintaining the AC effect of the capacitor 13 (C1) at the same level as in the mounting method according to related art.

Further, in the capacitor mounting method according to related art, the loop inductance between the capacitor (C2) on the printed circuit board 21 and the LSI 22 is (L1+L2+L3+L4). On the other hand, in the exemplary embodiment, the loop inductance between the capacitor (C2) on the printed circuit board 11 and the LSI 12 is (L1+L3). Accordingly, it is no longer affected by L2 and L4, and the improvement of the effect of the capacitor (C2) on the printed circuit board 11 can be expected.

If a signal line passes through a capacitor with a high dielectric constant, the dielectric loss increases compared to the case where there is no capacitor, which causes degradation of signal quality. On the other hand, according to the capacitor mounting method according to the exemplary embodiment, a signal line can be pulled out without passing through a capacitor, thus not leading to degradation of signal quality. Therefore, according to the exemplary embodiment, it is possible to mount the capacitor 13 without causing degradation of signal quality.

As described above, in this exemplary embodiment, the capacitor 13 is mounted on top of the LSI 12 which is mounted on top of the printed circuit board 11 in a stacked fashion. In this structure, the solder balls 15 and 17 are placed on the printed circuit board 11 side of the LSI 12, and the solder ball 15 is connected to the power supply or the ground of the printed circuit board 11, and the solder ball 17 is connected to the signal line of the printed circuit board 11. Further, the solder balls 14 and 16 placed on the capacitor 13 side of the LSI 12 are connected to the power supply or the ground of the capacitor 13. Thus, a connection between the LSI 12 and the thin-film capacitor 13 is made in a reverse manner to the capacitor mounting method according to related art, so that the capacitor is connected with low inductance like related art from a position that does not interfere with power supply and the signal line.

It is thereby possible in this exemplary embodiment to improve the DC characteristics of the power system while maintaining the AC effect of the decoupling capacitor at the same level as in related art (or allowing for the expectation of a higher effect than in related art). Further, because the signal line does not pass through the capacitor with a high dielectric constant, it is possible to prevent degradation of signal quality. It is thereby possible to provide a capacitor mounting method that enables a decoupling capacitor to be mounted in close proximity to an LSI without affecting power supply or a signal line, and a printed circuit board on which a capacitor is mounted by using the capacitor mounting method.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

What is claimed is:

1. A capacitor mounting method for mounting a capacitor in close proximity to an LSI, comprising:
mounting the capacitor on top of the LSI with solder balls or bumps placed therebetween, the LSI mounted on top of a printed circuit board with solder balls or bumps placed therebetween, in a stacked fashion.

2. The capacitor mounting method according to claim 1, wherein the solder balls or the bumps placed on the printed circuit board side of the LSI are connected to a power supply or a ground of the printed circuit board and to a signal line of the printed circuit board.

3. The capacitor mounting method according to claim 1, wherein the solder balls or the bumps placed on the capacitor side of the LSI are connected to a power supply or a ground of the capacitor.

4. The capacitor mounting method according to claim 2, wherein the solder balls or the bumps placed on the capacitor side of the LSI are connected to a power supply or a ground of the capacitor.

5. A printed circuit board on which a capacitor is mounted by using the capacitor mounting method according to one of claims 1.

6. A printed circuit board on which a capacitor is mounted by using the capacitor mounting method according to one of claims 2.

7. A printed circuit board on which a capacitor is mounted by using the capacitor mounting method according to one of claims 3.
